(19) United States
(12) Patent Application Publication
(10) Pub. No.: US 2025/0203261 A1
(43) Pub. Date: Jun. 19, 2025

(54) MICROPHONE THREE-DIMENSIONAL (3D) STACKED PACKAGE

(71) Applicant: QUALCOMM Incorporated, San Diego, CA (US)

(72) Inventors: Youngju PARK, InCheon (KR); Changhan Hobie YUN, San Diego, CA (US); Doosoub SHIN, Incheon (KR)

(21) Appl. No.: 18/539,770

(22) Filed: Dec. 14, 2023

(51) Int. Cl. H04R 1/08; H04R 1/06

(52) U.S. Cl. CPC H04R 1/08; H04R 1/06; H04R 2201/003; H04R 2201/401

(57) ABSTRACT

Certain aspects of the present disclosure generally relate to a microphone package, and more particularly, to a microphone package implemented using flip chip technology. An example microphone package generally includes an integrated circuit (IC), a substrate, and a transducer disposed between the substrate and the IC, wherein the IC or the substrate comprises a perforation above or below the transducer.

### TECHNICAL FIELD

Certain aspects of the present disclosure generally relate to a microphone package, and more particularly, to a microphone package implemented using flip chip technology.

### BACKGROUND

Electronic devices include computing devices such as desktop computers, notebook computers, tablet computers, smartphones, wearable devices like a smartwatch, internet servers, and so forth. These various electronic devices provide information, entertainment, social interaction, security, safety, productivity, transportation, manufacturing, and other services to human users. These various electronic devices may include one or more microphones for receiving sound waves and generating electrical signals representing the sound waves.

### SUMMARY

The systems, methods, and devices of the disclosure each have several aspects, no single one of which is solely responsible for its desirable attributes. Without limiting the scope of this disclosure as expressed by the claims which follow, some features will now be discussed briefly. After considering this discussion, and particularly after reading the section entitled “Detailed Description,” one will understand how the features of this disclosure provide the advantages described herein.

Certain aspects of the present disclosure are directed towards a microphone package. The microphone package generally includes an integrated circuit (IC), a substrate, and a transducer disposed between the substrate and the IC, wherein the IC or the substrate comprises a perforation above or below the transducer. The transducer may be disposed between the substrate and the IC in a vertical stack, wherein the substrate may be disposed above the transducer, which may be disposed above the IC, or wherein the IC may be disposed above the transducer, which may be disposed above the substrate.

Certain aspects of the present disclosure are directed towards a microphone package. The microphone package generally includes: an IC; a substrate; dielectric material disposed adjacent to the substrate, wherein one or more traces are disposed in the dielectric material; and a transducer, wherein at least one of the transducer or the IC is coupled to the one or more traces and wherein the substrate comprises a perforation above the transducer. In certain aspects, the dielectric material is disposed below the substrate. In this case, the transducer may be disposed below the substrate.

Certain aspects of the present disclosure are directed towards a method for manufacturing a microphone package. The method generally includes forming an IC, forming a perforation in the IC or a substrate, and stacking the substrate and the IC such that a transducer is disposed between the substrate and the IC, wherein the perforation is above or below the transducer after stacking the substrate and the IC.

Certain aspects of the present disclosure are directed towards a method for manufacturing a microphone package. The method generally includes: forming an IC; forming a perforation in a substrate; forming dielectric material adjacent to the substrate and one or more traces in the dielectric material; and stacking the substrate and the IC, wherein, after stacking the substrate and the IC, at least one of a transducer or the IC is coupled to the one or more traces and the perforation is above the transducer.

To the accomplishment of the foregoing and related ends, the one or more aspects comprise the features hereinafter fully described and particularly pointed out in the claims. The following description and the appended drawings set forth in detail certain illustrative features of the one or more aspects. These features are indicative, however, of but a few of the various ways in which the principles of various aspects may be employed.

### BRIEF DESCRIPTION OF THE DRAWINGS

So that the manner in which the above-recited features of the present disclosure can be understood in detail, a more particular description, briefly summarized above, may be by reference to aspects, some of which are illustrated in the appended drawings. It is to be noted, however, that the appended drawings illustrate only certain aspects of this disclosure and are therefore not to be considered limiting of its scope, for the description may admit to other equally effective aspects.

FIG. 1A illustrates a cross-section of an example microphone package having a top perforation, in accordance with certain aspects of the present disclosure.

FIG. 1B illustrates a cross-section of an example microphone package having a bottom perforation, in accordance with certain aspects of the present disclosure.

FIG. 2A illustrates a cross-section of an example microphone package having a top perforation and one or more filters, in accordance with certain aspects of the present disclosure.

FIG. 2B illustrates a cross-section of an example microphone package having a top perforation and implemented with a relatively large back volume, in accordance with certain aspects of the present disclosure.

FIG. 3A illustrates a cross-section of an example microphone package having a bottom perforation and one or more filters, in accordance with certain aspects of the present disclosure.

FIG. 3B illustrates a cross-section of an example microphone package having a bottom perforation and implemented with a relatively large back volume, in accordance with certain aspects of the present disclosure.

FIG. 4A illustrates a cross-section of an example microphone package with a top perforation and including a side-by-side integrated circuit (IC) and transducer stack, in accordance with certain aspects of the present disclosure.

FIG. 4B illustrates an example microphone package including a side-by-side IC and transducer stack and implemented with a relatively large back volume, in accordance with certain aspects of the present disclosure.

FIGS. 5A and 5B illustrate cross-sections of example microphone packages implemented with a filter using one or more vias, in accordance with certain aspects of the present disclosure.

FIG. 6A illustrates a cross-section of an example microphone package having a top perforation and implemented with a filter using one or more vias, in accordance with certain aspects of the present disclosure.

FIG. 6B illustrates a cross-section of an example microphone package using a bottom perforation and implemented with a filter using one or more vias, in accordance with certain aspects of the present disclosure.

FIGS. 7A-7H illustrate example techniques for fabricating a microphone package, in accordance with certain aspects of the present disclosure.

FIGS. 8 and 9 are flow diagrams illustrating example operations for manufacturing a microphone package, in accordance with certain aspects of the present disclosure.

To facilitate understanding, identical reference numerals have been used, where possible, to designate identical elements that are common to the figures. It is contemplated that elements disclosed in one aspect may be beneficially utilized on other aspects without specific recitation.

### DETAILED DESCRIPTION

Certain aspects of the present disclosure generally relate to a microphone package. Some microphone packages use wire bonding technology with a metal lid attachment, resulting in a relatively large microphone package size. Certain aspects of the present disclosure are directed to a microphone package using flip chip technology with a passive-on-glass (POG) filter design (e.g., a silicon-based filter) and a three-dimensional (3D) stack of a micro-electromechanical systems (MEMS) device and an application-specific integrated circuit (ASIC). In some cases, the ASIC may serve as the package substrate for the microphone package. The microphone 3D stacked package provides a smaller, thinner, faster, and/or lighter package than some conventional implementations. The microphone package described herein may include one or more filters. Such a filter may include a capacitive element (e.g., implemented as a metal-insulator-metal (MIM) structure) and/or an inductive element, which may be implemented using POG technology, for example. The microphone package may be formed by stacking a MEMS device and a POG die on or above an ASIC die using flip chip technology. The microphone package described herein may be used in any suitable microphone application, such as in mobile, wearable, internet of things (IoT), or automotive devices.

### Example Microphone Packages

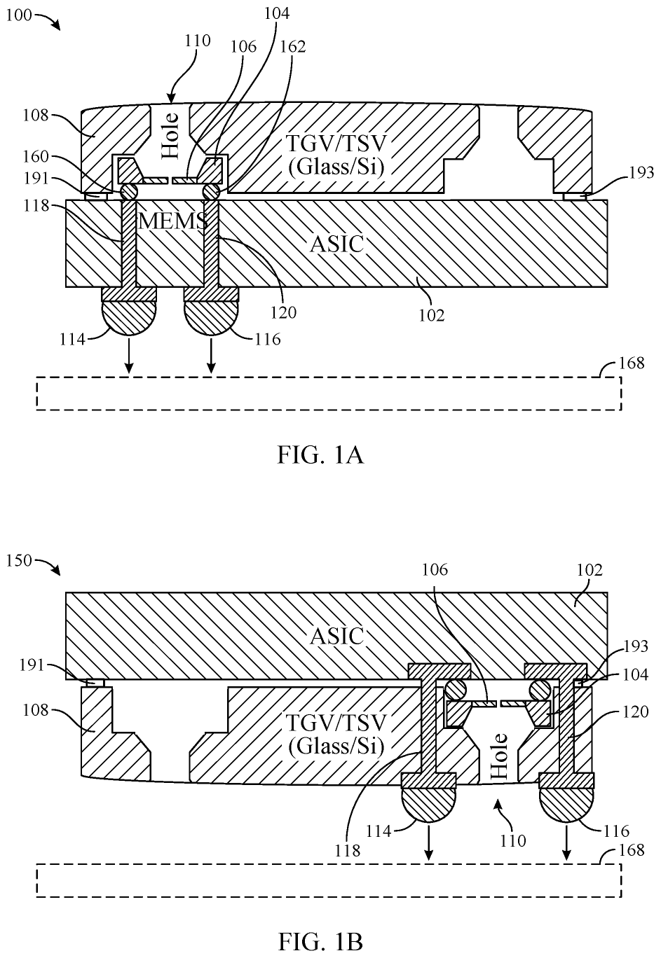

FIG. 1A illustrates a cross-section of an example microphone package 100 using a top perforation, in accordance with certain aspects of the present disclosure. As shown, the package 100 includes an ASIC 102 and a MEMS device 104 (also referred to herein as a “MEMS die”). As shown, the MEMS device 104 may have a piezoelectric structure 106 to convert sound pressure into an electrical signal, although the MEMS device 104 may have any suitable structure for transducing sound waves into electrical signals. The ASIC 102 may receive the electrical signal from the MEMS device 104 for buffering and amplifying the electrical signal. As shown, the package 100 may include a substrate 108 (e.g., a glass or silicon (Si) substrate), which does not function as a package substrate for the package 100. The substrate 108 may be disposed above the ASIC 102 in a stacked arrangement (as shown). The substrate 108 may include a perforation 110 (here, a top perforation), allowing sound waves to reach the piezoelectric structure 106 for the detection by the MEMS device 104. The perforation 110 may be disposed above and aligned with the MEMS device 104. The MEMS device 104 may be coupled to vias 118, 120 (e.g., through silicon vias (TSVs)) through the ASIC 102 using respective solder bumps 160, 162. The vias 118, 120 may be coupled to solder bumps 114, 116 for connection to a substrate 168 (e.g., a module substrate or a printed circuit board (PCB)). As shown, the ASIC 102 may be coupled to the substrate 108 using bonding elements 191, 193.

FIG. 1B illustrates a cross-section of an example microphone package 150 using a bottom perforation, in accordance with certain aspects of the present disclosure. As shown, the connection from the MEMS device 104 to solder bumps 114, 116 may be made using respective vias 118, 120 (e.g., TSVs or through glass vias (TGVs)) through the substrate 108 (e.g., as opposed to package 100 where the vias were through the ASIC 102). The perforation 110 may be made in the substrate 108 disposed on the bottom side of the package 150. The perforation 110 may be disposed below and aligned with the MEMS device 104.

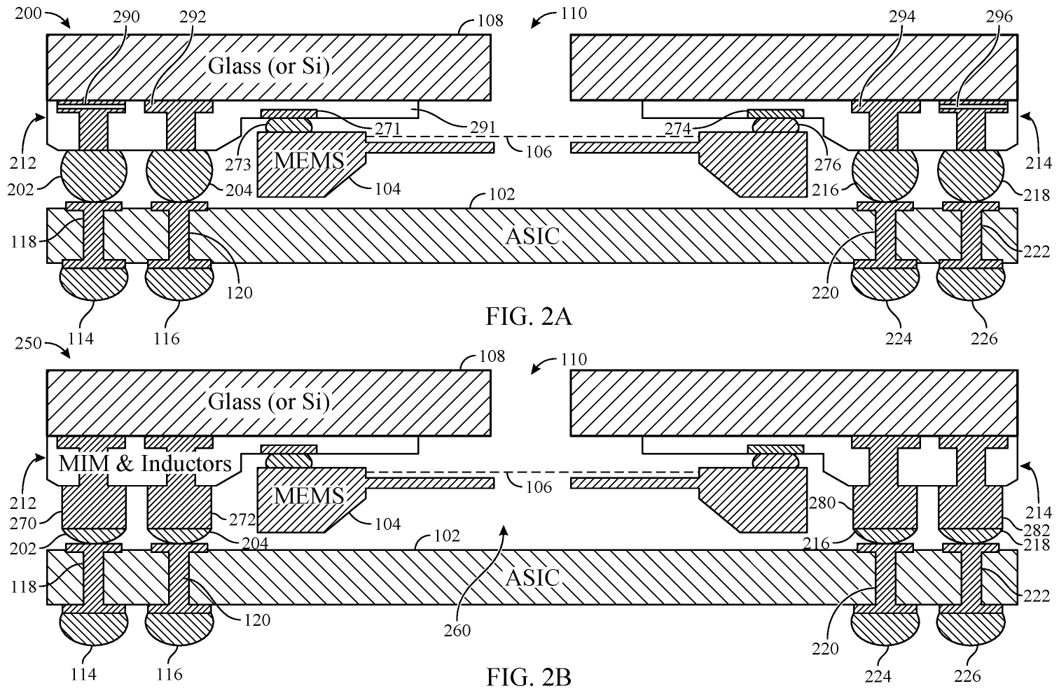

FIG. 2A illustrates a cross-section of an example microphone package 200 with a top perforation, in accordance with certain aspects of the present disclosure. As shown, the package 200 includes the ASIC 102 and the MEMS device 104, which may have the piezoelectric structure 106 to convert sound pressure into an electrical signal. The MEMS device 104 may be adjacent to the substrate 108 (e.g., part of a glass or silicon wafer). For example, a dielectric material 291 may be disposed between the MEMS device 104 and the substrate 108. The MEMS device 104 may be coupled, via solder bumps 273, 276, to respective pads 271, 274 (or other electrical conductors) formed in the dielectric material 291, which are coupled to traces in the dielectric material 291 for electrical communication from the MEMS device 104 to the ASIC 102 (e.g., through a filter as described in more detail herein).

The substrate 108 may include the perforation 110 for the reception of sound waves by the MEMS device 104. A filter 212 including a capacitive element 290 (e.g., implemented using a MIM structure) and/or an inductive element 292 may be disposed below a portion of the substrate 108. The filter 212 may be formed in in the dielectric material 291, as shown. The filter 212 may filter the electrical signal generated by the MEMS device 104, where the filtered electrical signal is provided to the ASIC 102. As shown, the filter 212 may be coupled to the ASIC 102 using solder bumps 202, 204, which may be coupled to vias 118, 120 of the ASIC 102, respectively.

Additionally or alternatively, the package 200 may include a filter 214 with a capacitive element 296 (e.g., implemented using a MIM structure) and inductive element 294 disposed below a portion of the substrate 108, as shown. The filter 214 may filter the electrical signal generated by the MEMS device 104, where the filtered electrical signal is provided to the ASIC 102. The filter 214 may be coupled to the ASIC 102 using solder bumps 216, 218. The solder bumps 216, 218 may be coupled to respective solder bumps 224, 226 at a bottom of the package 200 through respective vias 220, 222 (e.g., TSVs) of the ASIC 102.

FIG. 2B illustrates a cross-section of an example microphone package 250 with a top perforation and implemented with a relatively large back volume 260 (compared to the back volume of the microphone package 200 of FIG. 2A), in accordance with certain aspects of the present disclosure. The back volume 260 may refer to a volume of a space on the side of the piezoelectric structure 106 (or other sound transducer) that is opposite the perforation 110.

As shown in FIG. 2B, the filter 212 may be coupled to solder bumps 202, 204 through respective long (e.g., tall) conductive pillars 270, 272 (e.g., copper (Cu) pillars). Similarly, the filter 214 may be coupled to solder bumps 216, 218 through respective conductive pillars 280, 282 (e.g., Cu pillars). The long conductive pillars increase the back volume 260 (e.g., space between the MEMS device 104 and the ASIC 102) as compared to the microphone package 200 of FIG. 2A, providing more effective sound propagation and absorption for the microphone package 250.

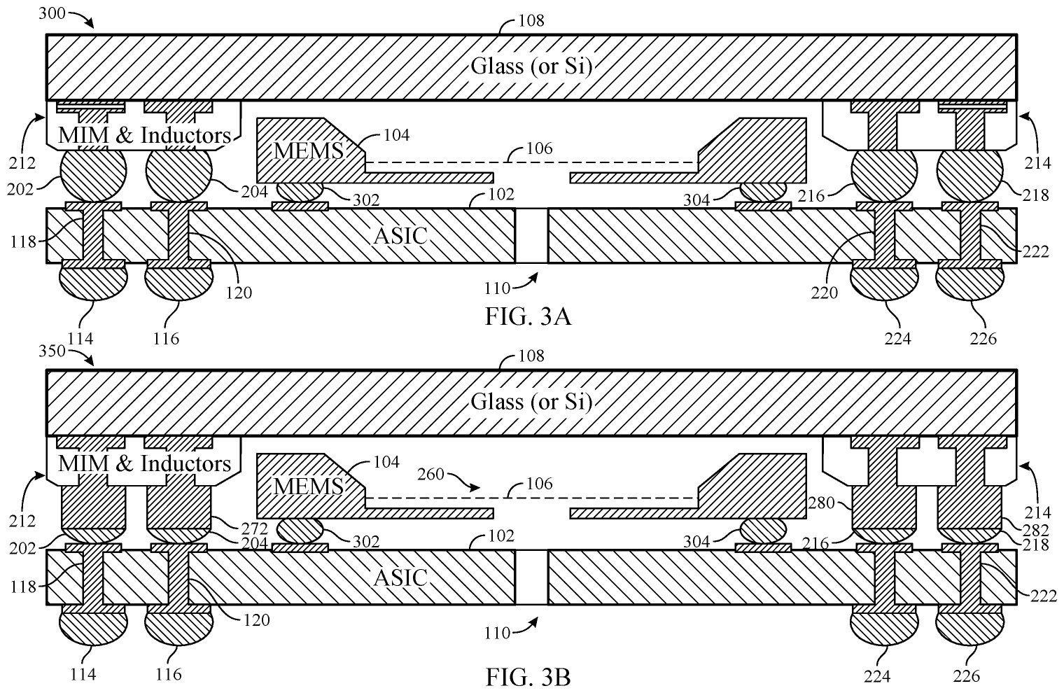

FIG. 3A illustrates a cross-section of an example microphone package 300 with a bottom perforation, in accordance with certain aspects of the present disclosure. As shown, instead of the substrate 108 having the perforation 110, the perforation is made in the ASIC 102. As shown, the MEMS device 104 may be coupled to the ASIC 102 via solder bumps 302, 304 (rather than being coupled to the substrate 108). The perforation 110 in the ASIC 102 may be below the piezoelectric structure 106 (or other sound transducer) of the MEMS device 104.

FIG. 3B illustrates a cross-section of an example microphone package 350 with a bottom perforation and implemented with a relatively large back volume 260 (compared to the back volume of the microphone package 300 of FIG. 3A), in accordance with certain aspects of the present disclosure. As described, the filter 212 may be coupled to solder bumps 202, 204 through respective pillars 270, 272, and the filter 214 may be coupled to solder bumps 216, 218 through respective pillars 280, 282, increasing the back volume 260 as described herein.

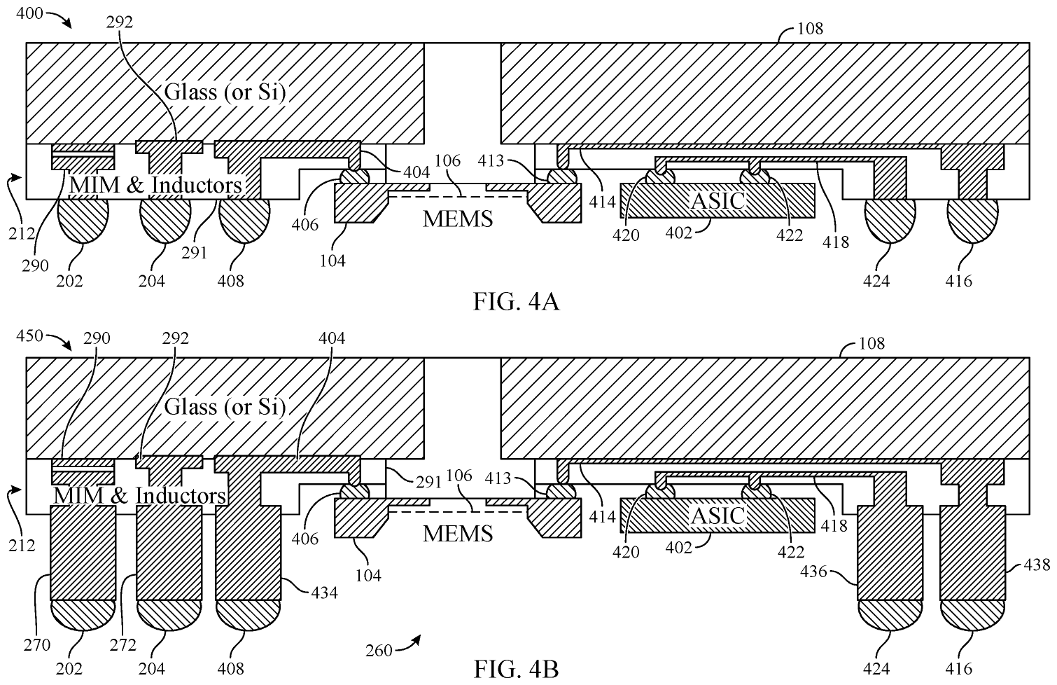

FIG. 4A illustrates a cross-section of an example microphone package 400 with a top perforation and including a side-by-side ASIC and MEMS device structure, in accordance with certain aspects of the present disclosure. The MEMS device 104 may be coupled to a trace 404 (e.g., formed in dielectric material 291) adjacent to the substrate 108 via a solder bump 406 (and an exposed conductive pad and a via coupled to the trace 404). The trace 404 may also be coupled to a solder bump 408 (e.g., through a via and an exposed conductive pad) for coupling to a substrate (e.g., substrate 168 shown in FIG. 1A). Similarly, the filter 212 may be coupled (e.g., through exposed conductive pads) to solder bumps 202, 204 for coupling to the substrate. The MEMS device 104 may also be coupled, via a solder bump 413 (and an exposed conductive pad and a via), to a trace 414 adjacent to the substrate 108 (e.g., formed in dielectric material 291) for coupling to a solder bump 416 (e.g., through a via and an exposed conductive pad). An ASIC 402 may be disposed laterally adjacent to the MEMS device 104, as shown. That is, the ASIC 402 and MEMS device 104 may be located side by side and below the substrate 108. The ASIC 102 may be coupled to traces (represented by trace 418) via solder bumps (represented by solder bumps 420, 422) for coupling to other solder bumps (represented by solder bump 424) (e.g., for coupling to the substrate 168 shown in FIG. 1A).

FIG. 4B illustrates a cross-section of an example microphone package 450 including a side-by-side ASIC and MEMS device structure implemented with a relatively large back volume 260 (compared to the back volume of the microphone package 400 of FIG. 4A), in accordance with certain aspects of the present disclosure. As shown, the filter 212 may be coupled to solder bumps 202, 204 via respective pillars 270, 272. Similarly, the traces 404, 418, 414 may be coupled to respective solder bumps 408, 424, 416 via respective pillars 434, 436, 438. The pillars 270, 272, 434, 436, 438 provide the increased back volume 260, as shown.

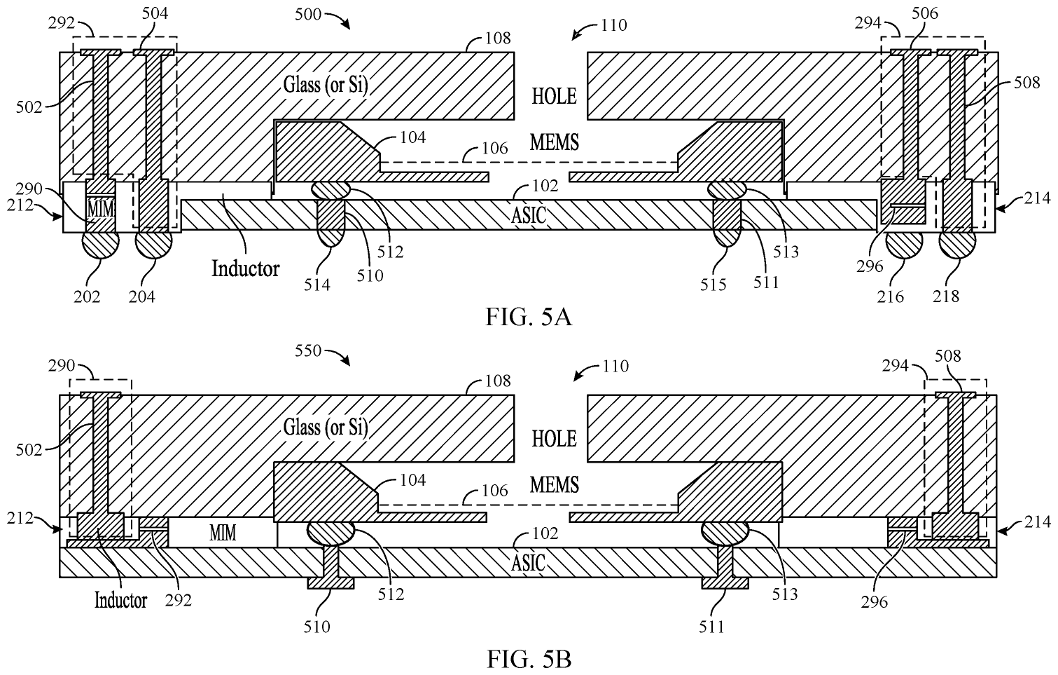

FIGS. 5A and 5B illustrate cross-sections of example microphone packages 500, 550, respectively, implemented with a filter (e.g., filter 212 or filter 214) using one or more TGVs or TSVs, in accordance with certain aspects of the present disclosure. As shown, the filter 212 may include a capacitive element 290 and an inductive element 292. The inductive element 292 may be implemented using vias 502, 504 through substrate 108, where the vias 502, 504 may be TGVs or TSVs, for example. In the package 500, the via 502 is coupled to the capacitive element 290. Similarly, filter 214 may include a capacitive element 296 and an inductive element 294 implemented using vias 506, 508. The ASIC 102 may be at least partially disposed between filters 212, 214. As shown, the MEMS device 104 may be adjacent to the substrate 108 and ASIC 102 (e.g., disposed between the substrate 108 and ASIC 102). The MEMS device 104 may be electrically coupled to vias 510, 511 of the ASIC 102 using respective solder bumps 512, 513. The vias 510, 511 may be coupled to respective solder bumps 514, 515 for coupling to a substrate (e.g., substrate 168 shown in FIG. 1A). As shown, in FIG. 5B, the inductive element 292 may be implemented using the via 502 (e.g., a single via through substrate 108 in this cross-sectional view, such as a TGV or TSV), and inductive element 294 may be implemented using the via 508 (e.g., a single via through substrate 108 in this cross-sectional view, such as a TGV or TSV). The ASIC 102 may span from a region below the filter 212 to a region below the filter 214, as shown. In the package 550, the capacitive element 292 is not coupled to a via though the substrate 108 (e.g., as compared to package 502 where the capacitive element is coupled to via 502).

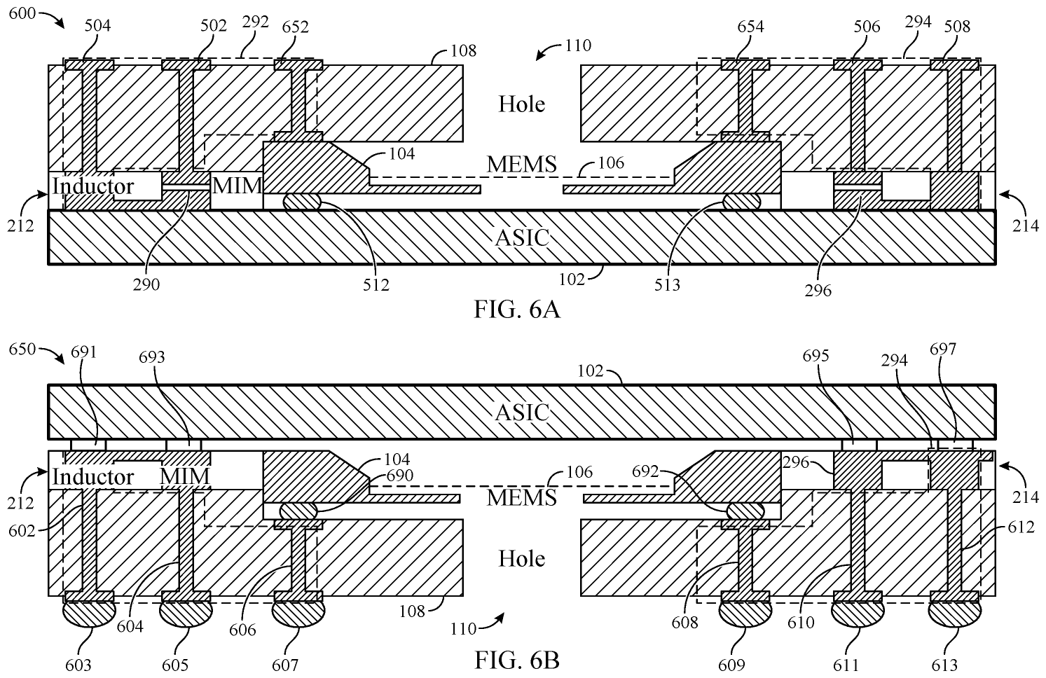

FIG. 6A illustrates a cross-section of an example microphone package 600 using a top perforation and implemented with a filter using one or more TGVs or TSVs, in accordance with certain aspects of the present disclosure. The inductive element 292 of filter 212 may be implemented using vias 502, 504, 652 in the substrate 108 (e.g., TGVs or TSVs), and the inductive element 294 of filter 214 may be implemented using vias 506, 508, 654 in the substrate 108. The MEMS device 104 may be coupled to the vias 652, 654, as shown, and then to the ASIC 102 via the filters 212, 214, additionally or alternatively to the MEMS device 104 being coupled to the ASIC 102 via the solder bumps 512, 513.

FIG. 6B illustrates a cross-section of an example microphone package 650 using a bottom perforation and implemented with a filter using one or more TGVs or TSVs, in accordance with certain aspects of the present disclosure. As shown, the inductive element 292 of filter 212 may be implemented using vias 602, 604, 606, which may be TGVs or TSVs through substrate 108, and the inductive element 294 of filter 214 may be implemented using vias 608, 610, 612, which may be TGVs or TSVs through substrate 108. The MEMS device 104 may be coupled to vias 606, 608 using respective solder bumps 690, 692. As shown, the vias 602, 604, 606, 608, 610, 612 may be coupled to solder bumps 603, 605, 607, 609, 611, 613, respectively, located at the bottom of the substrate 108. In some aspects, the filter 214 may be coupled to the ASIC 102 using bonding elements 695, 697 and the filter 212 may be coupled to the ASIC 102 using bonding elements 691, 693. The bonding elements conductive elements (e.g., Cu—Cu metallic or solder to Cu pads) establishing ASIC to MEMS device/glass connection. The bonding elements provide a gap between the filter/MEMS device and the ASIC providing a microphone back-volume.

### Example Operations for Fabricating a Microphone Package

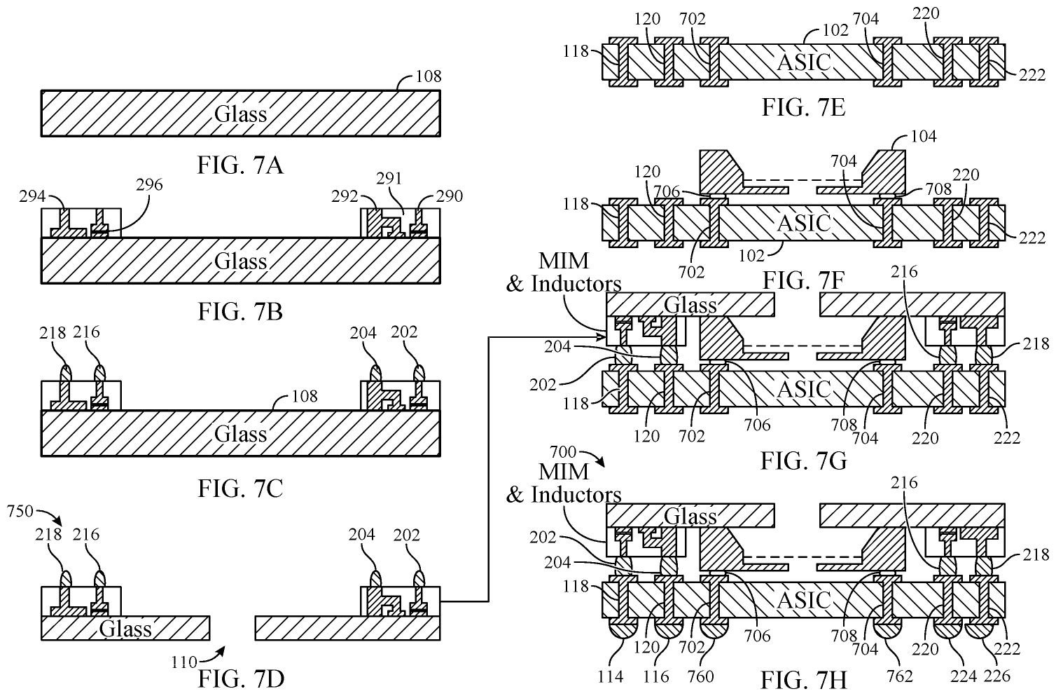

FIGS. 7A-7H illustrate example techniques for fabricating a microphone package 700, in accordance with certain aspects of the present disclosure. These techniques may be performed by a semiconductor processing facility, such as a fab house.

As shown in FIG. 7A, a raw glass wafer (e.g., substrate 108) may be obtained. As shown in FIG. 7B, the fabrication of the MIM structures (e.g., for implementing capacitive elements 290, 296) and inductive elements 292, 294 in dielectric material 291 for filters may be performed. As shown in FIG. 7C, plating and reflow for soldering may be performed, providing solder bumps 218, 216, 204, 202 for the filters. As shown in FIG. 7D, a wafer thinning process may be performed to reduce the thickness of the substrate 108, and a perforation 110 may be created, providing a POG die 750. For other aspects, the perforation 110 may be created in the raw glass wafer before the filters are added or in the glass wafer with the filters before the solder bumps are formed. As shown in FIG. 7E, the ASIC 102 may be provided, and the vias 118, 120, 702, 704, 220, 222 (e.g., TSVs) may be formed. The vias 118, 120, 702, 704, 220, 222 (or conductive pads coupled thereto) may be exposed (e.g., Cu exposed) on both bottom and top sides of the ASIC 102, as shown. As shown in FIG. 7F, the MEMS device 104 may be attached onto vias 702, 704 using solder bumps 706, 708, respectively. As shown in FIG. 7G, a POG flip chip attachment process may be performed. For example, the POG die 750 may be flipped and attached onto (e.g., stacked on) the ASIC 102, where solder bumps 202, 204, 216, 218 are coupled to vias 118, 120, 220, 222, respectively. As shown in FIG. 7H, a solder attach process may be performed. For example, solder bumps 114, 116, 760, 762, 224, 226 may be formed and used to attach vias 118, 120, 702, 704, 220, 222, respectively, to a substrate (e.g., substrate 168 of FIG. 1A).

Capacitive element and inductive element structures are important for MEMS microphone packages due to increasing power delivery and sensitivity specifications. However, MIM and inductive elements are typically not integrated into the microphone package due to causing the package size to be too large. Certain aspects of the present disclosure provide a MEMS device with POG (or Si) and TGV (or TSV) filter implementation that allows for a smaller microphone package. The microphone package described herein also provides higher heat dissipation using flip-chip technology and higher productivity manufacturability due to wafer level packaging rather than die-level individual packaging.

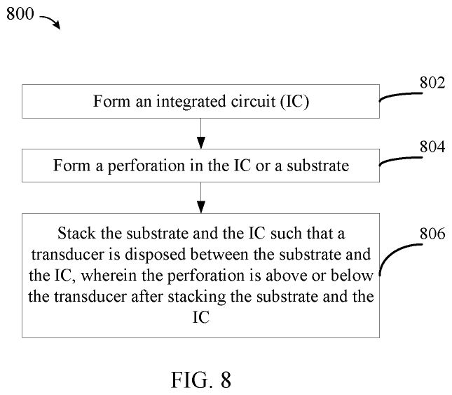

FIG. 8 is a flow diagram illustrating example operations 800 for device manufacturing, in accordance with certain aspects of the present disclosure. The operations 800 may be performed by a manufacturing facility, for example.

At block 802, the facility forms an integrated circuit (IC) (e.g., ASIC 102). At block 804, the facility forms a perforation (e.g., perforation 110) in the IC or a substrate (e.g., substrate 108, which may be glass or silicon).

At block 806, the facility stacks the substrate and the IC such that a transducer (e.g., MEMS device 104) is disposed between the substrate and the IC. The perforation may be above or below the transducer after stacking the substrate and the IC.

In some aspects, the facility forms dielectric material (e.g., dielectric material 291) adjacent to the substrate. The facility may electrically couple the transducer to one or more traces or pads (e.g., pad 271 in the dielectric material 291 shown in FIG. 2A).

In some aspects, the facility may form one or more passive elements adjacent to the substrate prior to stacking the substrate and the IC at block 806. The passive elements may include at least one of a capacitive element (e.g., capacitive element 290) or an inductive element (e.g., inductive element 292). In some implementations, the inductive element may be formed using one or more vias (e.g., vias 502, 504, 652 of FIGS. 5A, 5B, or 6A or vias 602, 604, 606 of FIG. 6B) through the substrate or IC.

In some aspects, after stacking the substrate and the IC at block 806, the one or more passive elements may be between a portion of the substrate and a portion of the IC. In some aspects, after stacking the substrate and the IC, the one or more passive elements may be adjacent to a lateral side of the transducer. In some aspects, the facility may form a dielectric material (e.g., dielectric material 291) adjacent to the substrate. The passive elements may be in the dielectric material. In some aspects, the facility may form one or more other passive elements (e.g., for filter 214) adjacent to the substrate. After stacking the substrate and the IC, the IC may be between the one or more passive elements and the one or more other passive elements (e.g., as shown in FIG. 5A).

In some aspects, the perforation may be formed in the substrate and disposed above the transducer (e.g., as shown in FIGS. 1A, 2A, 2B, 4A, 4B, 5A, 5B, and 6A) after the stacking. In some aspects, the perforation is formed in the substrate and below the transducer (e.g., as shown in FIGS. 1B and 6B). In some aspects, the perforation may be formed in the IC and below the transducer (e.g., as shown in FIGS. 3A and 3B).

In some aspects, the facility may form, before the stacking, one or more pillars (e.g., pillars 270, 272) to support the substrate above the IC after stacking the substrate and the IC at block 806. In some aspects, after stacking the substrate and the IC, a top side of the transducer is disposed adjacent to the substrate (e.g., as shown in FIGS. 3A and 3B). The facility may electrically couple a bottom side of the transducer to the IC via a solder bump (e.g., solder bump 302).

In some aspects, after stacking the substrate and the IC at block 806, a top side of the transducer is adjacent to the IC (e.g., as shown in FIGS. 5A and 5B). The facility may electrically couple a bottom side of the transducer to a via (e.g., via 510) of the substrate using a solder bump.

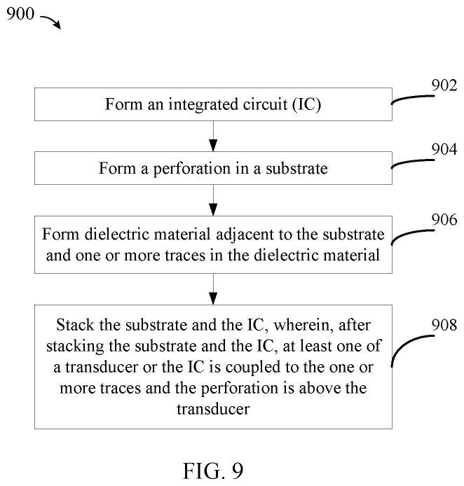

FIG. 9 is a flow diagram illustrating example operations 900 for device manufacturing, in accordance with certain aspects of the present disclosure. The operations 900 may be performed by a manufacturing facility, for example.

At block 902, the facility forms an integrated circuit (IC) (e.g., ASIC 102). At block 904, the facility forms a perforation in a substrate (e.g., substrate 108). At block 906, the facility forms dielectric material (e.g., dielectric material 291) adjacent to the substrate and one or more traces (e.g., trace 404 of FIGS. 4A and 4B) in the dielectric material. At block 908, the facility stacks the substrate and the IC. After stacking the substrate and the IC, at least one of a transducer (e.g., MEMS device 104) or the IC may be coupled to the one or more traces, and the perforation may be above the transducer.

In some aspects, the facility may form one or more passive elements in the dielectric material. The one or more passive elements may include at least one of a capacitive element (e.g., capacitive element 290) or an inductive element (e.g., inductive element 292). In some aspects, after stacking the substrate and the IC at block 908, the one or more passive elements are adjacent to a lateral side of the transducer (e.g., as shown in FIGS. 4A and 4B). The facility may form one or more pillars (e.g., pillars 270, 272, 434, 436, 438) supporting the substrate above another substrate (e.g., substrate 168 shown in FIG. 1A).

### EXAMPLE ASPECTS

Aspect 1: A microphone package, comprising: an integrated circuit (IC); a substrate; and a transducer disposed between the substrate and the IC, wherein the IC or the substrate comprises a perforation above or below the transducer.

Aspect 2: The microphone package of Aspect 1, further comprising dielectric material disposed adjacent to the substrate, wherein the transducer is coupled to one or more traces in the dielectric material.

Aspect 3: The microphone package of Aspect 1 or 2, wherein the substrate comprises a glass substrate or a silicon substrate.

Aspect 4: The microphone package according to any of Aspects 1-3, further comprising one or more passive elements disposed adjacent to the substrate.

Aspect 5: The microphone package of Aspect 4, wherein the passive elements comprise an inductive element and wherein the inductive element is implemented using one or more vias through the substrate or the IC.

Aspect 6: The microphone package of Aspect 4 or 5, wherein the one or more passive elements are disposed between a portion of the substrate and a portion of the IC.

Aspect 7: The microphone package according to any of Aspects 4-6, wherein the one or more passive elements are adjacent to a lateral side of the transducer.

Aspect 8: The microphone package according to any of Aspects 4-7, further comprising dielectric material adjacent to the substrate, wherein the passive elements are disposed in the dielectric material.

Aspect 9: The microphone package according to any of Aspects 4-8, further comprising one or more other passive elements disposed adjacent to the substrate, wherein the IC is disposed between the one or more passive elements and the one or more other passive elements.

Aspect 10: The microphone package according to any of Aspects 1-9, wherein the substrate comprises the perforation above the transducer.

Aspect 11: The microphone package according to any of Aspects 1-10, wherein the substrate comprises the perforation below the transducer.

Aspect 12: The microphone package according to any of Aspects 1-11, wherein the IC comprises the perforation below the transducer.

Aspect 13: The microphone package according to any of Aspects 1-12, wherein the transducer comprises a micro-electromechanical system (MEMS) device configured to convert sound waves into electrical signals.

Aspect 14: The microphone package according to any of Aspects 1-13, further comprising one or more pillars supporting the substrate above the IC.

Aspect 15: The microphone package according to any of Aspects 1-14, wherein a top side of the transducer is disposed adjacent to the substrate and wherein a bottom side of the transducer is coupled to a trace of the IC via a solder bump.

Aspect 16: The microphone package according to any of Aspects 1-15, wherein a top side of the transducer is disposed adjacent to the IC and wherein a bottom side of the transducer is coupled to a via of the substrate via a solder bump.

Aspect 17: The microphone package according to any of Aspects 1-16, further comprising an opening extending from a lateral side of the microphone package to a back volume of the transducer configured to provide ventilation for the transducer.

Aspect 18: A microphone package, comprising: an integrated circuit (IC); a substrate; dielectric material disposed adjacent to the substrate, wherein one or more traces are disposed in the dielectric material; and a transducer, wherein at least one of the transducer or the IC is coupled to the one or more traces and wherein the substrate comprises a perforation above the transducer.

Aspect 19: The microphone package of Aspect 18, wherein the substrate comprises a glass substrate or a silicon substrate.

Aspect 20: The microphone package of Aspect 18 or 19, further comprising one or more passive elements disposed in the dielectric material.

Aspect 21: The microphone package of Aspect 20, wherein the one or more passive elements are adjacent to a lateral side of the transducer.

Aspect 22: The microphone package according to any of Aspects 18-21, wherein the transducer comprises a micro-electromechanical system (MEMS) device.

Aspect 23: The microphone package according to any of Aspects 18-22, further comprising one or more pillars configured to support the substrate above another substrate.

Aspect 24: The microphone package according to any of Aspects 18-23, further comprising an opening extending from a lateral side of the microphone package to a back volume of the transducer configured to provide ventilation for the transducer.

Aspect 25: A method for manufacturing a microphone package, comprising: forming an integrated circuit (IC); forming a perforation in the IC or a substrate; and stacking the substrate and the IC such that a transducer is disposed between the substrate and the IC, wherein the perforation is above or below the transducer after stacking the substrate and the IC.

Aspect 26: The method of Aspect 25, further comprising; forming dielectric material adjacent to the substrate; and electrically coupling the transducer to one or more traces in the dielectric material.

Aspect 27: The method of Aspect 25 or 26, wherein the substrate comprises a glass substrate or a silicon substrate.

Aspect 28: The method according to any of Aspects 25-27, further comprising forming one or more passive elements adjacent to the substrate prior to stacking the substrate and the IC.

Aspect 29: The method of Aspect 28, wherein the passive elements comprise an inductive element and wherein the inductive element is formed using one or more vias through the substrate or IC.

Aspect 30: The method of Aspect 28 or 29, wherein, after stacking the substrate and the IC, the one or more passive elements are between a portion of the substrate and a portion of the IC.

Aspect 31: The method according to any of Aspects 28-30, wherein, after stacking the substrate, the one or more passive elements are adjacent to a lateral side of the transducer.

Aspect 32: The method according to any of Aspects 28-31, further comprising forming a dielectric material adjacent to the substrate, wherein the passive elements are in the dielectric material.

Aspect 33: The method according to any of Aspects 28-32, further comprising forming one or more other passive elements adjacent to the substrate, wherein, after stacking the substrate and the IC, the IC is between the one or more passive elements and the one or more other passive elements.

Aspect 34: The method according to any of Aspects 25-33, wherein the perforation is formed in the substrate and wherein the perforation is disposed above the transducer after the stacking.

Aspect 35: The method according to any of Aspects 25-34, wherein the perforation is formed in the substrate and wherein the perforation is disposed below the transducer after the stacking.

Aspect 36: The method according to any of Aspects 25-35, wherein the perforation is formed in the IC and wherein the perforation is disposed below the transducer after the stacking.

Aspect 37: The method according to any of Aspects 25-36, wherein the transducer comprises a micro-electromechanical system (MEMS) device.

Aspect 38: The method according to any of Aspects 25-37, further comprising forming, before the stacking, one or more pillars configured to support the substrate above the IC after stacking the substrate and the IC.

Aspect 39: The method according to any of Aspects 25-38, wherein, after stacking the substrate and the IC, a top side of the transducer is disposed adjacent to the substrate, the method further comprising electrically coupling a bottom side of the transducer to a trace of the IC via a solder bump.

Aspect 40: The method according to any of Aspects 25-39, wherein, after stacking the substrate and the IC, a top side of the transducer is adjacent to the IC, the method further comprising electrically coupling a bottom side of the transducer to a via of the substrate via a solder bump.

Aspect 41: A method for manufacturing a microphone package, comprising: forming an integrated circuit (IC); forming a perforation in a substrate; forming dielectric material adjacent to the substrate and one or more traces in the dielectric material; and stacking the substrate and the IC, wherein, after stacking the substrate and the IC, at least one of a transducer or the IC is coupled to the one or more traces and the perforation is above the transducer.

Aspect 42: The method of Aspect 41, wherein the substrate comprises a glass substrate or a silicon substrate.

Aspect 43: The method of Aspect 41 or 42, further comprising forming one or more passive elements in the dielectric material.

Aspect 44: The method of Aspect 43, wherein, after stacking the substrate and the IC, the one or more passive elements are adjacent to a lateral side of the transducer.

Aspect 45: The method according to any of Aspects 41-44, wherein the transducer comprises a micro-electromechanical system (MEMS) device.

Aspect 46: The method according to any of Aspects 41-45, further comprising forming one or more pillars configured to support the substrate above another substrate.

Within the present disclosure, the word “exemplary” is used to mean “serving as an example, instance, or illustration.” Any implementation or aspect described herein as “exemplary” is not necessarily to be construed as preferred or advantageous over other aspects of the disclosure. Likewise, the term “aspects” does not require that all aspects of the disclosure include the discussed feature, advantage, or mode of operation. The term “coupled” is used herein to refer to the direct or indirect coupling between two objects. For example, if object A physically touches object B and object B touches object C, then objects A and C may still be considered coupled to one another-even if objects A and C do not directly physically touch each other. For instance, a first object may be coupled to a second object even though the first object is never directly physically in contact with the second object. The terms “circuit” and “circuitry” are used broadly and intended to include both hardware implementations of electrical devices and conductors that, when connected and configured, enable the performance of the functions described in the present disclosure, without limitation as to the type of electronic circuits.

The apparatus and methods described in the detailed description are illustrated in the accompanying drawings by various blocks, modules, components, circuits, steps, processes, algorithms, etc. (collectively referred to as “elements”). These elements may be implemented using hardware, for example.

One or more of the components, steps, features, and/or functions illustrated herein may be rearranged and/or combined into a single component, step, feature, or function or embodied in several components, steps, or functions. Additional elements, components, steps, and/or functions may also be added without departing from features disclosed herein. The apparatus, devices, and/or components illustrated herein may be configured to perform one or more of the methods, features, or steps described herein.

It is to be understood that the specific order or hierarchy of steps in the methods disclosed is an illustration of exemplary processes. Based upon design preferences, it is understood that the specific order or hierarchy of steps in the methods may be rearranged. The accompanying method claims present elements of the various steps in a sample order, and are not meant to be limited to the specific order or hierarchy presented unless specifically recited therein.

The previous description is provided to enable any person skilled in the art to practice the various aspects described herein. Various modifications to these aspects will be readily apparent to those skilled in the art, and the generic principles defined herein may be applied to other aspects. Thus, the claims are not intended to be limited to the aspects shown herein, but are to be accorded the full scope consistent with the language of the claims, wherein reference to an element in the singular is not intended to mean “one and only one” unless specifically so stated, but rather “one or more.” Unless specifically stated otherwise, the term “some” refers to one or more. A phrase referring to “at least one of” a list of items refers to any combination of those items, including single members. As an example, “at least one of: a, b, or c” is intended to cover at least: a, b, c, a-b, a-c, b-c, and a-b-c, as well as any combination with multiples of the same element (e.g., a-a, a-a-a, a-a-b, a-a-c, a-b-b, a-c-c, b-b, b-b-b, b-b-c, c-c, and c-c-c or any other ordering of a, b, and c). All structural and functional equivalents to the elements of the various aspects described throughout this disclosure that are known or later come to be known to those of ordinary skill in the art are expressly incorporated herein by reference and are intended to be encompassed by the claims. Moreover, nothing disclosed herein is intended to be dedicated to the public regardless of whether such disclosure is explicitly recited in the claims. No claim element is to be construed under the provisions of 35 U.S.C. § 112 (f) unless the element is expressly recited using the phrase “means for” or, in the case of a method claim, the element is recited using the phrase “step for.”

It is to be understood that the claims are not limited to the precise configuration and components illustrated above. Various modifications, changes and variations may be made in the arrangement, operation and details of the methods and apparatus described above without departing from the scope of the claims.

1. A microphone package, comprising:
an integrated circuit (IC);
a substrate; and
a transducer disposed between the substrate and the IC, wherein the IC or the substrate comprises a perforation above or below the transducer.

2. The microphone package of claim 1, further comprising dielectric material disposed adjacent to the substrate, wherein the transducer is coupled to one or more traces in the dielectric material.

3. The microphone package of claim 1, wherein the substrate comprises a glass substrate or a silicon substrate.

4. The microphone package of claim 1, further comprising one or more passive elements disposed adjacent to the substrate.

5. The microphone package of claim 4, wherein the passive elements comprise an inductive element and wherein the inductive element is implemented using one or more vias through the substrate or the IC.

6. The microphone package of claim 4, wherein the one or more passive elements are disposed between a portion of the substrate and a portion of the IC.

7. The microphone package of claim 4, wherein the one or more passive elements are adjacent to a lateral side of the transducer.

8. The microphone package of claim 4, further comprising dielectric material adjacent to the substrate, wherein the passive elements are disposed in the dielectric material.

9. The microphone package of claim 4, further comprising one or more other passive elements disposed adjacent to the substrate, wherein the IC is disposed between the one or more passive elements and the one or more other passive elements.

10. The microphone package of claim 1, wherein the substrate comprises the perforation above the transducer.

11. The microphone package of claim 1, wherein the substrate comprises the perforation below the transducer.

12. The microphone package of claim 1, wherein the IC comprises the perforation below the transducer.

13. The microphone package of claim 1, wherein the transducer comprises a micro-electromechanical system (MEMS) device configured to convert sound waves into electrical signals.

14. The microphone package of claim 1, further comprising one or more pillars supporting the substrate above the IC.

15. The microphone package of claim 1, wherein a top side of the transducer is disposed adjacent to the substrate and wherein a bottom side of the transducer is coupled to a trace of the IC via a solder bump.

16. The microphone package of claim 1, wherein a top side of the transducer is disposed adjacent to the IC and wherein a bottom side of the transducer is coupled to a via of the substrate via a solder bump.

17. The microphone package of claim 1, further comprising an opening extending from a lateral side of the microphone package to a back volume of the transducer configured to provide ventilation for the transducer.

18. A microphone package, comprising:
an integrated circuit (IC);
a substrate;
dielectric material disposed adjacent to the substrate, wherein one or more traces are disposed in the dielectric material; and
a transducer, wherein at least one of the transducer or the IC is coupled to the one or more traces and wherein the substrate comprises a perforation above the transducer.

19. The microphone package of claim 18, wherein the substrate comprises a glass substrate or a silicon substrate.

20. The microphone package of claim 18, further comprising one or more passive elements disposed in the dielectric material.

21. The microphone package of claim 20, wherein the one or more passive elements are adjacent to a lateral side of the transducer.

22. The microphone package of claim 18, wherein the transducer comprises a micro-electromechanical system (MEMS) device.

23. The microphone package of claim 18, further comprising one or more pillars configured to support the substrate above another substrate.

24. The microphone package of claim 18, further comprising an opening extending from a lateral side of the microphone package to a back volume of the transducer configured to provide ventilation for the transducer.

25. A method for manufacturing a microphone package, comprising:
forming an integrated circuit (IC);
forming a perforation in the IC or a substrate; and
stacking the substrate and the IC such that a transducer is disposed between the substrate and the IC, wherein the perforation is above or below the transducer after stacking the substrate and the IC.

26. The method of claim 25, further comprising;
forming dielectric material adjacent to the substrate; and
electrically coupling the transducer to one or more traces in the dielectric material.

27. The method of claim 25, wherein the substrate comprises a glass substrate or a silicon substrate.

28. The method of claim 25, further comprising forming one or more passive elements adjacent to the substrate prior to stacking the substrate and the IC.

29. The method of claim 28, wherein the passive elements comprise an inductive element and wherein the inductive element is formed using one or more vias through the substrate or IC.

30. A method for manufacturing a microphone package, comprising:
forming an integrated circuit (IC);
forming a perforation in a substrate;
forming dielectric material adjacent to the substrate and one or more traces in the dielectric material; and
stacking the substrate and the IC, wherein, after stacking the substrate and the IC, at least one of a transducer or the IC is coupled to the one or more traces and the perforation is above the transducer.
